(19) United States
(12) Patent Application Publication
(10) Pub. No.: US 2017/0164495 A1
(43) Pub. Date: Jun. 8, 2017

(54) SUBSEA CONVERTER MODULE

(71) Applicant: Siemens Aktiengesellschaft, Muenchen (DE)

(72) Inventors: Fredrik Gundersen AARSKOG, Oslo (NO); Knut Schonhowd KRISTENSEN, Hamar (NO)

(73) Assignee: Siemens Aktiengesellschaft, Muenchen (DE)

(21) Appl. No.: 15/322,478

(22) PCT Filed: Aug. 12, 2014
(86) PCT No.: PCT/EP2014/067192

§ 371 Date: Dec. 28, 2016

(51) Int. Cl. H05K 5/06; E21B 33/035; H04R 1/44; H02M 7/00; H01R 13/523; H05K 7/14; E21B 41/00

(52) U.S. Cl. CPC H05K 5/067; H05K 7/14; E21B 33/035; E21B 41/0007; H02M 7/00; H01R 13/523; H04R 1/44

(57) ABSTRACT

A subsea converter module is provided. A subsea enclosure is configured to provide a fluid tight sealing of the inside of the subsea enclosure to the outside of the subsea enclosure. At least one converter unit for providing frequency conversion of AC electrical power is disposed in the subsea enclosure. The subsea enclosure includes a mounting portion for mounting the subsea converter module to a base module of a subsea converter. The subsea enclosure includes an end wall that provides separation towards the base module when the subsea converter module is mounted to the base module.

### PRIORITY STATEMENT

This application is the national phase under 35 U.S.C. §371 of PCT International Application No. PCT/EP2014/067192 which has an International filing date of Aug. 12, 2014, which designated the United States of America, the entire contents of which are hereby incorporated herein by reference.

### FIELD

An embodiment of the present invention generally relates to a subsea converter module, to a subsea converter and/or to a method of assembling a subsea converter module.

### BACKGROUND

Due to the increasing energy demand, offshore oil and gas production is moving into deeper waters. For ensuring an efficient and secure production of hydrocarbons from a subsea well, processing facilities are being installed at the ocean floor. Such subsea installations can comprise a range of components, including pumps, compressors and the like as well as a power grid for providing such components with electric power. The power grid may for example comprise a subsea transformer, subsea switchgear and subsea variable speed drives (VSDs). Such components of a subsea installation may be installed at water depths of 3,000 meters or more, so that they are exposed to pressures up to or even in excess of 300 bars. To protect such components from the corrosive seawater and allow operation at these high pressures, they are provided with subsea enclosures.

Pressure compensated enclosures are known in which the internal pressure is equalized or balanced to the pressure prevailing in the ambient seawater. A pressure compensator may be used for such purpose. Such enclosures are generally filled with a dielectric liquid, in order to keep volume changes due to the increase in pressure and due to temperature changes relatively low. The dielectric liquid can further support the cooling of electric and electronic components disposed therein.

For operating subsea equipment such as subsea pumps and compressors, it is desirable to make use of a subsea frequency converter which can provide AC electric power at variable frequency. Such converter can be used to drive AC motors at variable speed and can thus be termed variable speed drive (VSD). Speed control of AC electric motors comprised in such subsea equipment thus becomes possible. Different types of equipment and different installation sites might require variable speed drives having different power ratings, different control ranges or different requirements regarding the quality of the output AC electric power. When providing subsea variable speed drives for such different requirements, new subsea enclosures are required. Changing the configuration of a variable speed drive is thus a time- and cost-intensive procedure and furthermore requires significant development and qualification efforts.

Furthermore, such variable speed drive has components such as capacitors which are prone to oxidation if exposed to air, e.g. during assembly of the variable speed drive. This can reduce the overall reliability and expected lifetime of the variable speed drive.

A variable speed drive can have a plurality of converter units, for example power cells comprising a rectifier circuit and an inverter circuit, and a DC link capacitor. If during assembly and testing, a failure occurs, it might be necessary to replace or clean all power cells due to high levels of contamination. Also, due to the large number of converter units, the assembly of the subsea converter can be a time consuming process. During assembly and repair, the converter unit is exposed to air for a significant amount of time.

Even further, if a fault occurs in a power cell during operation, the fault can spread to other power cells of the variable speed drive, for example due to contamination of a medium in which the power cells are disposed.

### SUMMARY

The inventors have recognized that there is a need for improving subsea converters and for mitigating at least some of the drawbacks mentioned above.

The claims describe embodiments of the invention.

According to an embodiment of the invention, a subsea converter module is provided which comprises a subsea enclosure which is configured to provide a fluid tight sealing of the inside of the subsea enclosure to the outside of the subsea enclosure, and at least one converter unit for providing frequency conversion of AC electrical power. The converter unit is disposed in the subsea enclosure. A mounting portion on the subsea enclosure, in particular a flange, is provided for mounting the converter module to a base module of a subsea converter. The subsea enclosure comprises an end wall that provides separation towards the base module. The end wall may thus form an inner wall towards the base module; it may form an interface towards the base module. The subsea converter module further comprises a pressure compensator mounted to the end wall and electrical connections through the end wall for electrically contacting the converter unit. The pressure compensator is configured to provide pressure balancing between a medium present inside the subsea enclosure and a medium present outside the subsea enclosure in proximity or adjacent to the end wall, i.e. to a medium that is in contact with the pressure compensator on the outer side of the end wall. Accordingly, when the subsea converter module is mounted to the base module, the pressure compensator provides pressure balancing between the pressure in the converter module and the pressure in the base module.

According to a further embodiment of the invention, a method of assembling a subsea converter module is provided. The method comprises the steps of providing a subsea enclosure, wherein the subsea enclosure has a mounting portion, in particular a flange, for mounting the converter module to a base module of a subsea converter and further having a sealing portion for sealing the subsea enclosure to the base module; and of disposing at least one converter unit which is configured to provide frequency conversion of AC electrical power in the subsea enclosure. Further steps of the method include the providing of an end wall of the subsea enclosure having electrical connections through the end wall for electrically contacting the converter unit, mounting a pressure compensator to the end wall wherein the pressure compensator is configured to provide pressure balancing, and mounting the end wall to the subsea enclosure so as to provide a fluid tight sealing of the inside of the subsea enclosure to the outside of the subsea enclosure. It should be clear that the order of these method steps is not fixed but may be changed, the end wall may for example be mounted to the subsea enclosure prior to mounting the pressure compensator to the end wall. By such method, advantages similar to the ones outlined further above with respect to the subsea converter module may be achieved.

### BRIEF DESCRIPTION OF THE DRAWINGS

The foregoing and other features and advantages of the invention will become further apparent form the following detailed description read in conjunction with the accompanying drawings. In the drawings, like reference numerals refer to like elements.

FIG. 1 is a schematic block diagram illustrating a subsea converter according to an embodiment of the invention.

FIGS. 2A to 2C are schematic drawings showing a subsea converter according to an embodiment of the invention.

FIGS. 3A and 3B are schematic drawings showing details of a converter unit that may be used with embodiments of the invention.

FIGS. 4A and 4B are schematic drawings showing a subsea converter module according to an embodiment of the invention.

FIGS. 5A and 5B are schematic drawings showing details of the subsea converter module of FIG. 4.

FIGS. 6A and 6B are schematic drawings showing perspective views of the subsea converter module of FIG. 4.

### DETAILED DESCRIPTION OF THE EXAMPLE EMBODIMENTS

According to an embodiment of the invention, a subsea converter module is provided which comprises a subsea enclosure which is configured to provide a fluid tight sealing of the inside of the subsea enclosure to the outside of the subsea enclosure, and at least one converter unit for providing frequency conversion of AC electrical power. The converter unit is disposed in the subsea enclosure. A mounting portion on the subsea enclosure, in particular a flange, is provided for mounting the converter module to a base module of a subsea converter. The subsea enclosure comprises an end wall that provides separation towards the base module. The end wall may thus form an inner wall towards the base module; it may form an interface towards the base module. The subsea converter module further comprises a pressure compensator mounted to the end wall and electrical connections through the end wall for electrically contacting the converter unit. The pressure compensator is configured to provide pressure balancing between a medium present inside the subsea enclosure and a medium present outside the subsea enclosure in proximity or adjacent to the end wall, i.e. to a medium that is in contact with the pressure compensator on the outer side of the end wall. Accordingly, when the subsea converter module is mounted to the base module, the pressure compensator provides pressure balancing between the pressure in the converter module and the pressure in the base module.

By such configuration, a predetermined number of converter units can be provided in the subsea converter module. Further subsea converter modules can then be provided in order to obtain the required total number of converter units for a subsea converter of a desired configuration. By this modularized approach, it becomes possible to assemble each subsea converter module separately. Accordingly, the assembling time for each subsea converter module can be relatively short, since it only includes a relatively low number of converter units, for example one, two or three converter units. Thus, the electric components of the converter units, such as a capacitor, are only exposed for a relatively short time to air during assembly, which may thus increase the overall reliability and expected lifetime of the respective converter units and thus of the assembled subsea converter. Furthermore, since the subsea enclosure of the subsea converter module provides fluid tight sealing, the subsea converter module can be assembled and can be stored until the whole subsea converter is assembled, or can be stored as a spare part, without the risk of deterioration of the electric components of the converter units.

By making use of such subsea converter module, the converter units of the subsea converter module can be tested and verified separately, which may result in an reduced overall failure rate of a subsea converter assembled from such separate subsea converter modules. Furthermore, in a subsea converter, the propagation of a failure may be avoided, since the subsea enclosure of each subsea converter module provides a fluid tight sealing, so that a contamination of a medium filling one subsea enclosure of such module, which may be caused by an electrical fault or the like, cannot propagate and pollute the medium filling the subsea enclosures of other subsea converter modules. Spreading of contamination throughout the whole subsea converter, and a resulting total system shutdown may thus be avoided.

In an embodiment, the converter unit, in particular the subsea enclosure, may comprise a sealing portion for sealing the subsea enclosure to the base module. The sealing portion may be provided in form of a seal seat, a sealing face or a seal, in particular a circumferential seal, e.g. a metal seal or resilient seal. The mounting portion may comprise the sealing portion. As an example, the mounding portion may be a flange comprising the sealing portion in form of a seal seat, sealing surface or a seal.

The sealing portion may be arranged circumferentially around the pressure compensator mounted to the end wall and the electrical connections provided through the end wall.

The sealing portion may be arranged so as to enable a sealing of at least the part of the end wall comprising the pressure compensator and the electrical connections from a surrounding environment when the subsea converter module is mounted to the base module. When the converter module is installed subsea, the pressure compensator and the electrical connections can accordingly be sealed from the subsea environment, in particular the seawater. They may only be in contact with a dielectric liquid or gas filling the base module.

In an embodiment, the end wall may be surrounded by the sealing portion. The end wall can thus be sealed from the surrounding environment when the subsea converter module is mounted to the base module.

Note that the in some embodiments, the sealing portion and/or the mounting portion may also be provided by the end wall, which forms part of the subsea enclosure.

In an embodiment, the subsea converter module further comprises a valve, such as an electrically or hydraulically or manually operated valve. The valve may be provided in the end wall. The valve may be configured to allow, in an open position, an exchange of fluid through the end wall. In operation, such valve may avoid a constant cyclic operation of the pressure compensator, since pressure balancing may occur by a fluid flow through the open valve. In case of a fault, the valve may be closed in order to provide separation between subsea converter modules of a subsea converter. In other embodiments, the valve may be closed during normal operation. Furthermore, the subsea enclosure may be filled with a liquid through the valve, for example during assembly.

The electrical connections through the end wall may comprise at least an electrical power input connection for supplying AC or DC electrical power to the at least one converter unit and an electrical power output connection for outputting converted AC or DC electrical power. In such configuration, no further connections through the subsea enclosure may need to be provided, other than the connections through the end wall. Preferably, AC electrical power is supplied to the converter module and converted AC electrical power is given out by the converter module. Yet in some embodiments, DC electrical power may be supplied to the subsea converter module, e.g. from a common rectifier, and in further embodiments, the converter units may produce a DC output.

The electrical power input connection may comprise at least three electrical connections for supplying three phase AC electrical power through the end wall. Preferably, the at least three electrical connections are provided per converter unit comprised within the subsea enclosure. As an example, for such three-phase system, six electrical connections may be provided for a power input for two converter units (2×3), or nine electrical connections may be provided for a power input for three converter units (3×3). The electrical power output connection may comprise at least one or two electrical connections through the end wall for outputting at least single phase AC electrical power. Preferably, two such electrical connections are provided for the power output, on which single phase AC electrical power is provided.

In an embodiment, the electrical connections through the end wall may comprise penetrators or bushings that are mounted in the end wall. As an example, cast resin bushings may be used, but other types of bushings may also be employed. Such bushing may have a conductor that is surrounded by isolating material, such as cast resin. The bushing may for example have a screw hole for connecting conductors thereto, such as the conductor of a cable or bus bar connection.

The subsea converter module may furthermore comprise a control connection through the end wall for providing control signals to the at least one converter unit. In an embodiment, the control connection is a fibre optic connection. In other embodiments, an electrical connection for providing control signals may be provided. As an example, by means of such control connection, the converter units may be controlled in order to adjust the AC frequency that is generated by the converter units.

In an embodiment, the end wall is circular, and the pressure compensator is provided in the center of the end wall. The electrical connections may be provided in the end wall circumferentially around the pressure compensator. As an example, three to twelve, e.g. nine, bushings for input electrical connections and two bushings for output electrical connections may be provided around the pressure compensator in the end plate. By such configuration, a compact subsea converter module may be achieved, and assembly may be facilitated.

The end wall may comprise an opening, in particular a central opening, which is sealed by the pressure compensator. The pressure compensator is thus exposed to the pressure from inside the subsea enclosure and the pressure prevailing for example in the base module of the subsea converter.

In an embodiment, the pressure compensator comprises a flexible element for pressure compensation. The flexible element is selected from a group consisting of a bellows, a bladder or a membrane. The flexible element closes the opening in the end wall. Efficient and reliable pressure compensation may thus be achieved.

The pressure compensator may for example comprise a first bellows portion mounted to the end wall and a second bellows portion that is folded back into the first bellows portion. The first bellows portion may for example be mounted around the above mentioned opening. The space between the first and the second bellows portions may for example be in fluid communication with the interior of the subsea enclosure, and the space surrounded by the second bellows portion may be in fluid communication with the interior of a base module of the subsea converter. A compact pressure compensator which can compensate relatively large volume variations may thus be obtained.

The subsea enclosure may be filled with a dielectric liquid, in particular oil, such as transformer oil or silicon oil, or with an ester-based liquid, such as Midel.

The subsea enclosure may for example separate surrounding seawater from the dielectric liquid filling the subsea enclosure.

In an embodiment, the subsea enclosure comprises a tank or a canister that is, apart from an opening, hermetically sealed. As an example, a steel tank or a steel canister having such opening may be used. The opening is surrounded by the mounting portion and is closed and sealed by the end wall. The end wall may for example be a circular plate, or disk, sealing the opening.

The subsea enclosure may have a tubular structure or shape that is closed at one end and provided with the mounting portion in form of a mounting flange at the other end. The other end has an opening that is closed by the end wall, and the end wall may be provided by a circular plate mounted in the opening. In particular, the subsea enclosure may have a cylindrical shape. The converter units may for example be mounted along the length of the tubular structure. The subsea enclosure may thus be adjusted to the number of converter units by simply adjusting the length of the tubular structure. A relatively simple subsea enclosure which would not need to be re-qualified upon an adaptation of the number of converter units may thus be obtained.

In an embodiment, the converter module is releasably mountable to the base module of the subsea converter. The mounting portion may be configured to form a fluid tight seal with the base module. As an example, both base module and the subsea enclosure may have corresponding flanges which can be mounted together. The releasable mounting may occur by means of screws or bolts.

The subsea enclosure may comprise at least two, preferably at least three converter units. By providing for example six or 18 subsea converter modules, a subsea converter having eighteen or 54 converter units may thus be obtained. The number of converter units may for example be increased in order to increase the quality of the generated AC electrical power, for example by providing higher pulse rectification, e.g. 18 pulse or 36 pulse rectification, or for increasing the power output of the subsea converter.

According to a further embodiment of the invention, a subsea converter for providing a frequency conversion of AC electric power is provided. The subsea converter comprises at least one converter module that is configured in accordance with any of the above described embodiments. As an example, the subsea converter may comprise three, six, nine, twelve or even eighteen such subsea converter modules. By making use of the subsea converter modules, a stepwise assembly of the subsea converter becomes possible, for example by first assembling the respective subsea converter modules, testing and verifying of the respective subsea converter modules, and finally assembling the whole subsea converter. The time for which electric components of the converter units are exposed to air may thus be minimized. Furthermore, since the subsea converter modules can be verified and tested independently, it may be easier to find and avoid failures, and the exchange of a faulty converter unit may be facilitated.

The subsea converter may further comprise at least one base module having a subsea enclosure and electrical connections disposed within the subsea enclosure. The at least one converter module may be coupled to the base module. The electrical connections of the base module are coupled to the electrical connections which lead through the end wall of the converter module, for example to the above mentioned bushings. The subsea enclosure of the converter module is mounted to the subsea enclosure of the base module, in particular by means of the mounting portion, for example by means of a flange.

A fluid tight sealing may be a liquid tight sealing, e.g. a sealing against a dielectric liquid such as an oil or the like, or a sealing against water, in particular seawater. The sealing portion may be configured to provide or to at least contribute (e.g. in form of a seal seat) to a liquid tight sealing between the subsea enclosure of the subsea converter module and the base module, in particular a subsea enclosure of the base module.

According to a further embodiment of the invention, a method of assembling a subsea converter module is provided. The method comprises the steps of providing a subsea enclosure, wherein the subsea enclosure has a mounting portion, in particular a flange, for mounting the converter module to a base module of a subsea converter and further having a sealing portion for sealing the subsea enclosure to the base module; and of disposing at least one converter unit which is configured to provide frequency conversion of AC electrical power in the subsea enclosure. Further steps of the method include the providing of an end wall of the subsea enclosure having electrical connections through the end wall for electrically contacting the converter unit, mounting a pressure compensator to the end wall wherein the pressure compensator is configured to provide pressure balancing, and mounting the end wall to the subsea enclosure so as to provide a fluid tight sealing of the inside of the subsea enclosure to the outside of the subsea enclosure. It should be clear that the order of these method steps is not fixed but may be changed, the end wall may for example be mounted to the subsea enclosure prior to mounting the pressure compensator to the end wall. By such method, advantages similar to the ones outlined further above with respect to the subsea converter module may be achieved.

In an embodiment, the method may be performed so as to assemble a subsea converter module in any of the above outlined configurations. Furthermore, method steps described further above with respect to the subsea converter module may form part of embodiments of the method.

The method may further comprise a step of connecting electrical conductors inside the subsea enclosure of the subsea converter module to bushings provided in the end wall in order to provide the electrical connections. Cables or bus bars may be arranged inside the subsea enclosure and may be connected to the bushings.

In an embodiment, the method further comprises the step of filling the subsea enclosure of the subsea converter module with a dielectric liquid. It may for example be filled through a filling port or a valve provided in the end wall. In other embodiments, it may be filled prior to mounting the end wall.

A further embodiment provides a method of assembling a subsea converter, comprising the steps of providing a base module, mounting at least one subsea converter module having any of the above outlined configurations to the base module by means of the mounting portion and coupling the electrical connections of the converter module to respective electrical connections of the base module. The base module may in a further step be filled with dielectric liquid. In operation, a valve in the end wall of the subsea converter module may be opened to allow fluid exchange between the base module and the converter module.

Electrical connections provided in the base module may comprise bus bars or cables. Furthermore, they may comprise bypass contactors so that a subsea converter module can be electrically bypassed in such configuration. A subsea converter module may thus be electrically isolated from the remaining modules of the subsea converter, thereby preventing electrical fault propagation.

The method of assembling the subsea converter module may furthermore comprise a step of conditioning or drying a dielectric liquid filling the subsea enclosure and sealing the subsea enclosure. Accordingly, it can be ensured that the electric components of the converter units are disposed in a suitable environment, thus increasing the reliability and lifetime of the converter units, in particular increasing the reliability and lifetime of capacitors comprised in the converter units. When the dielectric liquid is conditioned or dried, and the subsea converter module is sealed thereafter, it may be stored for prolonged periods of time before it is used with a subsea converter.

It is to be understood that the features mentioned above and those yet to be explained below can be used not only in the respective combinations indicated, but also in other combinations or in isolation, without leaving the scope of the present invention.

In the following, embodiments of the invention will be described in detail with reference to the accompanying drawings. It is to be understood that the following description of the embodiments is given only for the purpose of illustration and is not to be taken in a limiting sense.

It should be noted that the drawings are to be regarded as being schematic representations only, and elements in the drawings are not necessarily to scale with each other. Rather, the representation of the various elements is chosen such that their function and general purpose become apparent to a person skilled in the art. It is also to be understood that the coupling of physical or functional units as shown in the drawings and described hereinafter, does not necessarily need to be a direct connection or coupling, but may also be an indirect connection or coupling, for example a connection or a coupling with one or more additional intervening elements, such as fuses, circuit breakers, and the like.

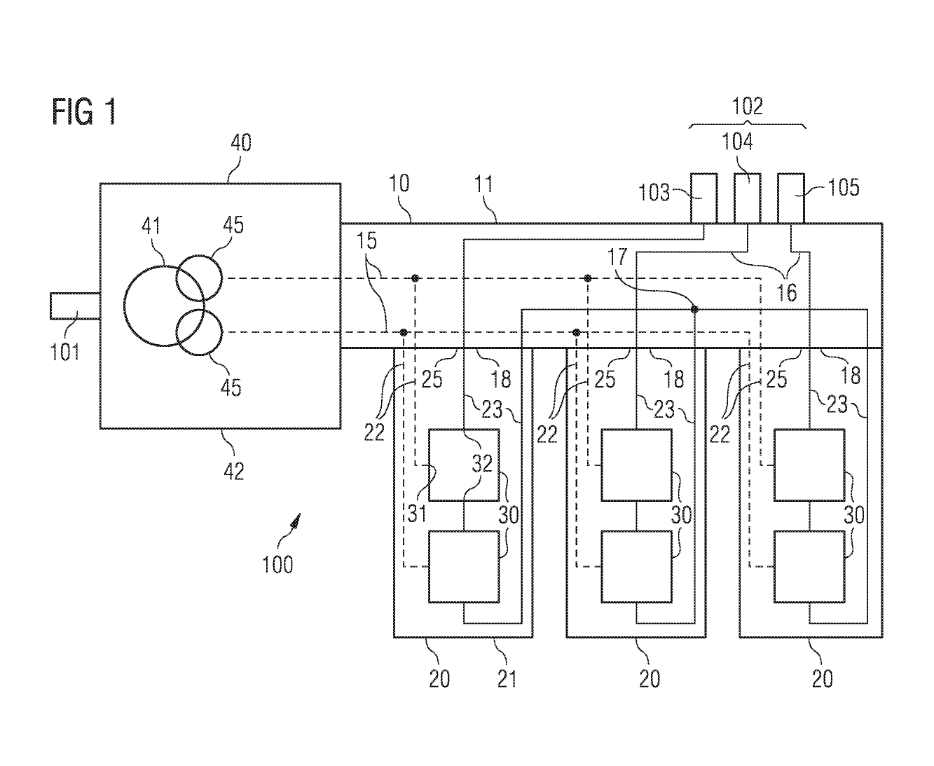

FIG. 1 shows schematically a subsea converter 100 according to an embodiment of the invention. In the example shown in FIG. 1, the subsea converter 100 includes the base module 10, three subsea converter modules 20 (short: converter modules) coupled to the base module 10, and a transformer module 40, to which the base module 10 is coupled. Due to this modular approach, the subsea converter 100 is herein also termed modular subsea converter.

The transformer module 40 comprises the input transformer 41. Furthermore, a power input 101 is provided at the transformer module 40 for receiving three-phase AC electric power as an input to the subsea converter 100. The input transformer 41 includes a primary winding and two secondary windings 45, which are configured to produce an AC output that is phase-shifted with respect to each other. Since the example of FIG. 1 shows a three-phase system, the secondary windings 45 are each provided for the three-phases and thus produce a three-phase output (i.e. each secondary winding 45 in fact comprises three secondary windings for the three phases).

In other embodiments, the input transformer 41 may be configured differently. It may for example comprise more or fewer secondary windings 45, for example one, three, or six secondary windings, with the power outputs of the respective secondary windings being phase-shifted with respect to each other. In even other configurations, two or more input transformers may be provided, and the secondary windings may be distributed between these two or more input transformers. An example configuration may include three input transformers each having two secondary windings 45, thus producing six phase-shifted AC power outputs. In further configurations of the modular subsea converter 100, no transformer module 40 may be provided, or the input transformer 41 may be provided within the base module 10.

The base module 10 comprises the electrical connections 15, by which three-phase AC electric power is supplied from the power source in form of the transformer 41 to the subsea converter modules 20. Base module 10 furthermore includes the electrical connections 16 which supply converted AC electric power from the subsea converter modules 20 to the power output 102. The power output 102 is a three-phase power output, the three phases 103, 104 and 105 being shown separately. Note that the dashed electrical connections 15 each include three phases.

Each converter module 20 comprises an end wall 25 which seals an opening in the respective subsea enclosure 21. In the embodiment of FIG. 1, each subsea converter module 20 has two electrical power input connections 22 and two electrical power output connections 23. Note that in the schematic representation of FIG. 1, each of the electrical power input connections 22 is a three phase connection while the illustrated electrical power output connections 23 belong to the same single phase power output, as outlined above. Bushings can be provided in the end wall 25 to lead the electrical connections 22, 23 through the end wall 25.

In the embodiment of FIG. 1, each converter module 20 comprises two converter units 30. Each converter unit 30 has an input connection 31 at which it receives three-phase AC electric power from the input transformer 41 via the electrical connections 15 and 22. Each converter unit 30 further includes a power output 32 at which the respective converter module 20 provides converted single-phase AC electric power. By means of the two terminals of the single phase power output 32, the converter units 30 within the same converter module 20 are connected in series. One terminal of this series connection is connected together with the respective terminals of the other converter modules 20 in the star point 17. The other terminal of this series connection provides the converted single phase AC power output of the respective converter module 20, which is connected via the electrical connections 23 and 16 to the power output 102 (note that the reference numerals 103, 104 and 105 denote the three phases of power output 102). By controlling the converter units 30 appropriately, the modular subsea converter 100 is thus capable of converting a three-phase AC power received at power input 101 into a three-phase AC power given out at power output 102 of variable AC frequency. This power may be used to drive subsea equipment, such as pumps or compressors. The modular subsea converter 100 may thus be termed modular subsea variable speed drive (modular subsea VSD).

The modular subsea converter 100 may be configured in different ways. Fewer or more converter units 30, which may be power cells, can be provided. As an example, for some applications, modular subsea converter 100 may only comprise one secondary winding 45 and only one converter unit 30 per phase of the power output 102 (i.e. a total of three converter units 30). In other embodiments, three, four, five, six or even more converter units 30 may be provided per phase of the power output 102. The input transformer 41 may comprise a secondary winding 45 for each such converter unit 30 (for all three phases). For example, if six converter units 30 are provided per output phase, the input transformer 41 may comprise six secondary windings 45. For three output phases, a total of 3×6=18 converter units 30 may be obtained. Note that more than three converter modules 20 may be provided. As an example, for each output phase 102, two or more converter modules 20 can be provided, each comprising for example between one and three converter units 30.

The converter units 30 for one output phase 103, 104, 105 of power output 102 are connected in series, so as to achieve a high quality AC power output and/or to increase the output voltage. In other embodiments, further converter units 30 may be connected in parallel for the same output phase of power output 102, so as to increase the power rating of the power output 102, i.e. to drive equipment and loads that require a high input power. Again, such additional converter units 30 may be comprised within the same converter module 20 or additional converter modules 20 can be provided.

As can be seen from the above description, the modular subsea converter 100 has a very variable configuration in which different power qualities, voltage levels and power levels of output AC electric power can be achieved. The subsea converter 100 thus has a modular configuration which allows the adding and removing of converter units 30 for different applications without the need to redesign the enclosure of the subsea converter 100 and go through a new qualification, whereby significant savings in development effort, qualification costs and required time can be achieved.

To achieve the modular variability, the base module 10 is provided which comprises the electrical connections 15, 16 and as mentioned above may comprise further equipment such as control and monitoring equipment. Base module 10 has mounting portions, in particular flanges, to which the converter modules 20 can be mounted. In the example of FIG. 1, three mounting portions are provided on base module 10, and three converter modules 20 are mounted thereto. In other configurations, base module 10 may for example comprise two, four, six or more mounting portions for converter modules. The configuration of the subsea converter 100 can thus easily be changed by adding or removing converter modules 20 from the base module 10.

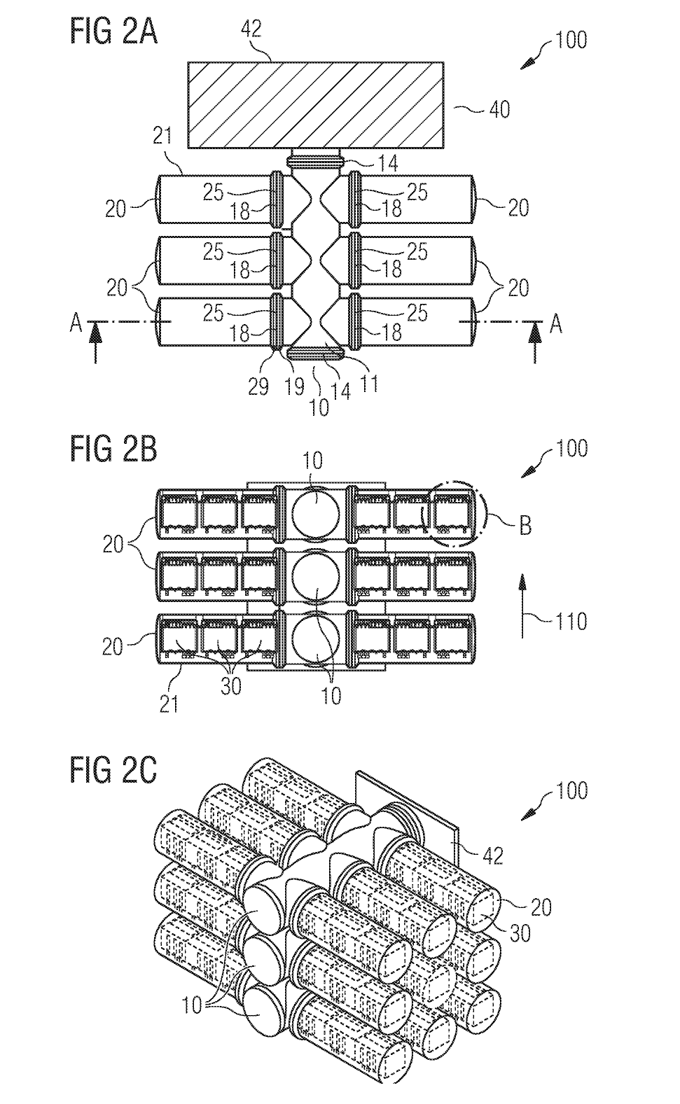

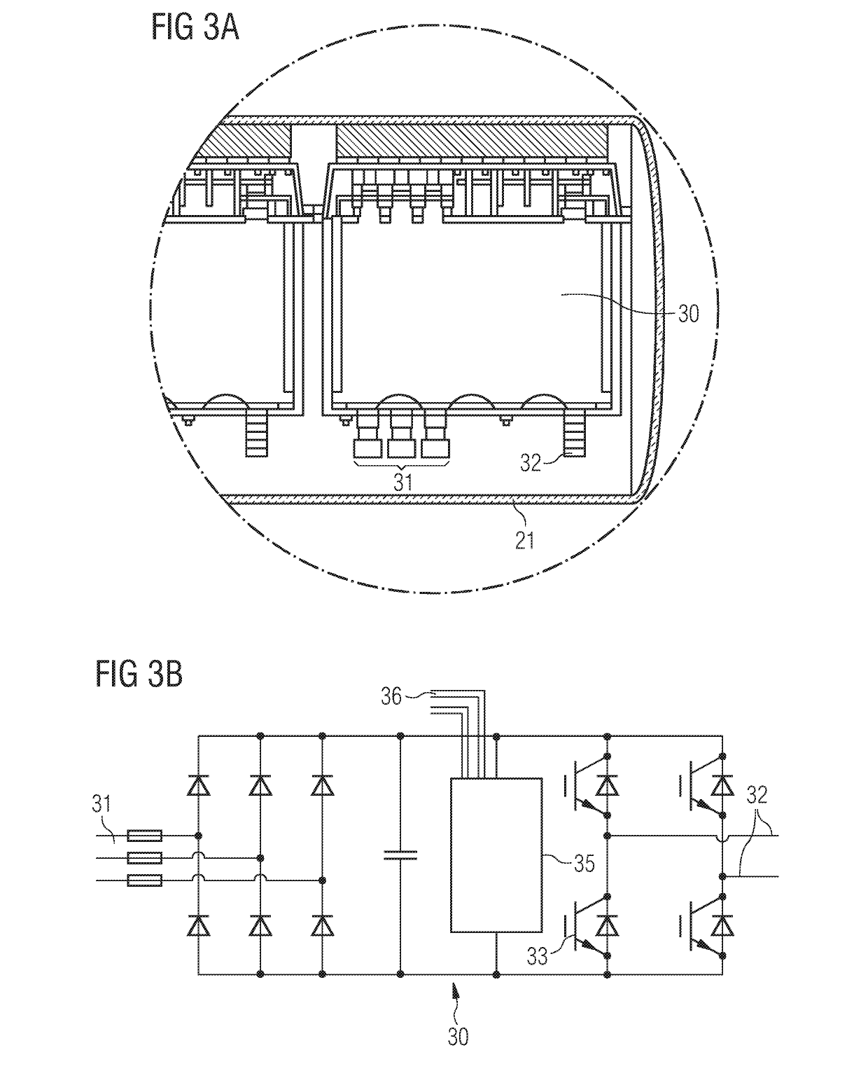

FIGS. 2 and 3 show particular embodiments of the general concept of the modular subsea converter 100 of FIG. 1. Accordingly, the explanations given above are equally applicable to the embodiments illustrated in FIGS. 2 and 3.

FIG. 2A shows a top view of the modular subsea converter 100 according to an embodiment of the invention. A first base module 10 to which six converter modules 20 are mounted is visible. Base module 10 is mounted to a transformer module 40. The base module 10 has a subsea enclosure 11 comprising six mounting portions 18 for converter modules 20. It further includes two additional mounting portions 14. At one mounting portion 14, the base module 10 is mounted to a subsea enclosure 42 of the transformer module 40, while the other mounting portion 14 is closed by a blind cover. The other mounting portion 14 may also be used to mount other equipment, such as a control module. In some embodiments, the blind cover may include one or more of the power outputs 102. In other embodiments, the power outputs 102 may be provided at different positions on the subsea enclosure 11 of base module 10 or they may be provided at the subsea enclosure 42 of transformer module 40.

Converter modules 20 each comprise a subsea enclosure 21 which has a tubular structure. At one end, the subsea enclosure 21 is closed, and at the other end, it comprises a mounting portion 29, in particular a flange, which is mounted to a corresponding mounting portion 18, in particular a flange 19, of the subsea enclosure 11 of base module 10. The subsea enclosure 21 further comprises a sealing portion, which is in the illustrated embodiment provided at the mounting portion. In particular, the sealing portion is a seal seat or sealing surface provided at the flange. A seal, such as a metal or resilient O-ring seal is used for sealing between the mounting portion 29 of subsea enclosure 21 and the mounting portion 18 of the base module's subsea enclosure 11.

The subsea enclosure 21 has the shape of a cylinder, one end of which is closed, for example by a welded plate, while the other end comprises the mounting portion 29. Accordingly, by adjusting the longitudinal extension, i.e. the length of the tubular structure in particular the cylinder, the size of the subsea enclosure 21 can be adjusted in a relatively simple way, without changing the further configuration of the subsea enclosure 21. Differently sized subsea enclosures 21 can thus be provided without the need for a new qualification thereof.

FIG. 2B is a sectional front view of the modular subsea converter 100 taken along the line A-A shown in FIG. 2A. As can be seen, two further base modules 10 are provided, they arranged below the base module 10 visible in FIG. 2A. Arrow 110 denotes the vertical direction (i.e. the direction from the sea bottom to the sea surface, i.e. the direction perpendicular to the earth's surface). All three base modules 10 are mounted to the subsea enclosure 42 of transformer module 40. Each base module 10 is provided for an output phase of the power output 102. Accordingly, the converter units 30 which are connected in series and/or in parallel for providing a single phase of the AC power output 102 are located within the same horizontal plane.

FIG. 2B shows that in each converter module 20, three converter units 30 are provided. In the example embodiment of FIG. 2, 6×3=18 converter units 30 are thus provided for each output phase of power output 102.

FIG. 2C is a perspective view of the modular subsea converter 100 of FIGS. 2A and 2B. As can be seen, all three base modules 10 are mounted to a wall of subsea enclosure 42 of transformer module 40 (only a section of the subsea enclosure 42 is shown). For illustrating the arrangement of the converter units 30, the subsea enclosures 21 of the converter modules 20 are shown transparent.

In the example of FIG. 2, each base module 10 has a subsea enclosure 11 with six converter module mounting portions 18. In other configurations, base modules may for example have only two converter mounting portions 18, and plural of such base modules may be mounted together for increasing the number of available mounting portions 18. Accordingly, the base module 10 illustrated in FIG. 2A may in other embodiments be composed of three individual base modules mounted together. Accordingly, the subsea converter 100 is highly modular and can be configured easily for a wide range of applications.

FIG. 3A shows a converter unit 30 in form of a power cell, it is an enlargement of the area marked with ‘B’ in FIG. 2B. Converter unit 30 has its own enclosure and is mounted via a heat conducting element to the subsea enclosure 21 of the converter module 20. The three-phase power input connection 31 of the converter unit 30 is shown. Furthermore, the single phase output connection 32 of the converter unit 30 is illustrated. By providing the converter modules 20 with a tubular subsea enclosure 21, which is surrounded by ambient seawater when installed subsea, an efficient cooling of the converter units 30 can be achieved. This is further improved by the thermal coupling of the converter unit 30 to the wall of subsea enclosure 21.

FIG. 3B shows an example configuration of a converter unit 30, which can be used in embodiments of the invention. The three-phase power input connection 31 is connected to a diode rectifier stage, which generates an intermediate DC voltage. A DC link capacitor is furthermore provided. A power supply, driver and control circuitry 35 may be coupled to the DC link. Control connections 36, which can in particular be optical fibres and/or electrical connections, are connected to the control circuitry 35, thus allowing control and monitoring of the converter unit 30. For generating an AC output power at variable AC frequency, controllable semiconductor switches 33 are provided which are controlled by the control circuitry 35. These may for example be insulated gate bipolar transistors (IGBTs). These generate the single phase AC power at output 32. Each converter unit 30 may effectively comprise an H-bridge converter.

In other configurations, the rectifier stage may not be part of the converter unit, there may for example be a common rectifier for plural converter units or the like. Accordingly, there may only be two electrical power input connections for DC electrical power per converter unit or for all converter units into the converter module.

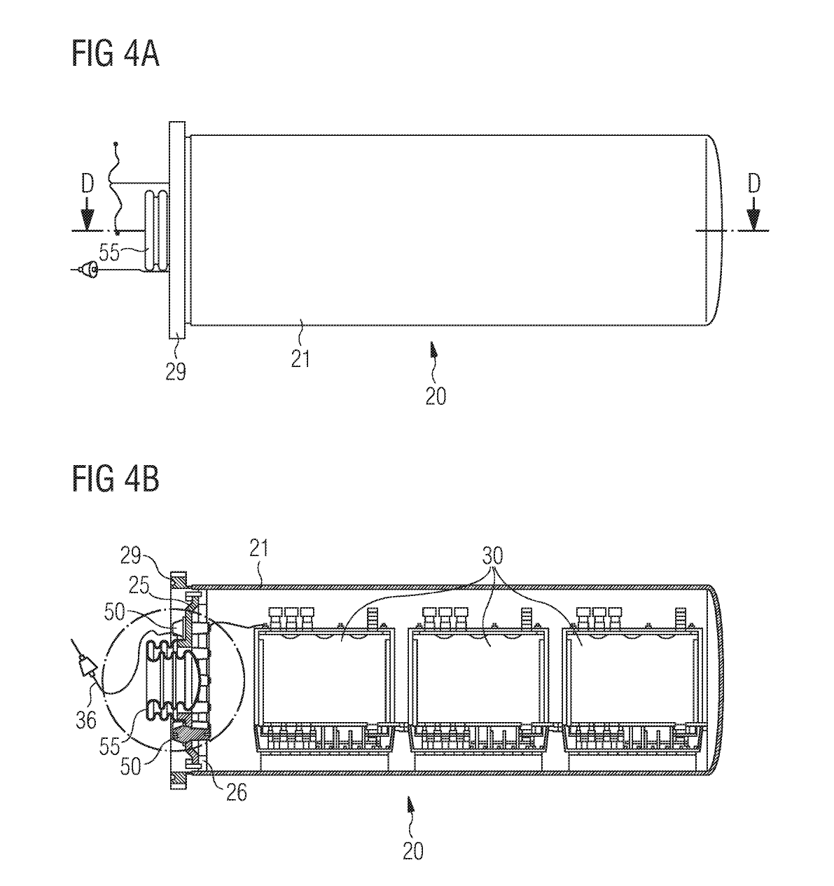

FIG. 4 is a schematic diagram showing details of an embodiment of a subsea converter module 20. FIG. 4B is a sectional side view of the module shown in FIG. 4A taken along the line D-D. Three converter units 30 are disposed in the subsea enclosure 21. As can be seen in FIG. 4B, the subsea enclosure 21 is a steel tank or a steel canister of cylindrical shape that is closed on its right hand end. On the left hand end, it has an opening that is sealed by the end wall 25. End wall 25 is provided by a circular plate that is mounted, in particular bolted or clamped, to an internal flange 26 provided circumferentially inside the subsea enclosure 21. End wall 25 may for example be sealed to the inner flange 26 by means of O-ring seals or the like to provide a fluid tight sealing.

The mounting portion 29 is provided by means of a flange which surrounds the end wall 25. Accordingly, when the subsea converter module 20 is mounted to the base module 10, the end wall 25 is only in contact with medium filling the base module, but is not in contact with seawater. The end wall 25 provides separation to the base module 10, and further provides an interface thereto. For this purpose, the end wall 25 comprises bushings 50 by means of which the electrical connections 22, 23 are led through the end wall 25. In particular, each electrical connection 22, 23 comprises a respective bushing in end wall 25 and an electrical conductor, such as a cable and/or a bus bar which provides the electrical connections to the respective input or output of the converter units 30.

Furthermore, the pressure compensator 55 is provided on the end wall 25. Pressure compensator 55 provides pressure balancing between the inside of the subsea enclosure 21 and the inside of the subsea enclosure 11 of base module 10. On one side, the pressure compensator 55 is in contact with a dielectric liquid filling the chamber provided by subsea enclosure 21 and on the other side in contact with dielectric liquid filling the chamber provided by subsea enclosure 11. Subsea converter module 20 can thus be operated while it is sealed in a liquid tight manner to the base module 10. Expansion of the liquid in the chamber formed by subsea enclosure 21, e.g. due to heating, does thus not lead to an increase in pressure, but the expansion is compensated by the pressure compensator 55, which deforms to increase the volume of the chamber.

Pressure compensator 55 provides a pressure equalization between the pressure inside the converter module and the pressure inside the base module. It should be clear that the pressure does not need to be equal, but the pressure compensator may be biased to one or the other side, e.g. by an intrinsic spring constant or by some biasing element such as a spring, so that e.g. the pressure inside the converter module can be slightly higher than the pressure inside the base module.

There is further provided a sealing portion which in the example of FIG. 4 is provided to surround the end wall 25. In the example illustrated, the sealing portion is provided by a seal seat or sealing surface on the flange, which is indicated with a recess in the flange. The sealing portion may comprise the seal, such as an O-ring seal itself, yet the seal may also be a separate part. When mounted to the base module, the sealing portion provides sealing against the base module so that the components mounted to the end plate, in particular the pressure compensator and the electrical connections, are sealed from the ambient environment, in particular from the subsea environment when installed subsea.

In other configurations, the sealing portion and/or the mounting portion may be provided by the end wall itself, which is part of the subsea enclosure. The end wall may for example be a lid which is mounted to an external flange of the cylindrical enclosure body. Such type of end wall may at its outer side have a further flange for mounting to the base module, and may have include the sealing portion in form or a circumferential seal seat or sealing face which surrounds the central portion of the end wall, in particular the portion to which the compensator 55 and the electrical connections are mounted.

Further, if the liquid filling base module 10 is polluted, for example due to a fault in the electric system of the base module or one of the connected converter modules, the contaminated liquid cannot enter the subsea enclosure 21, so that the converter units 30 are protected from such contamination.

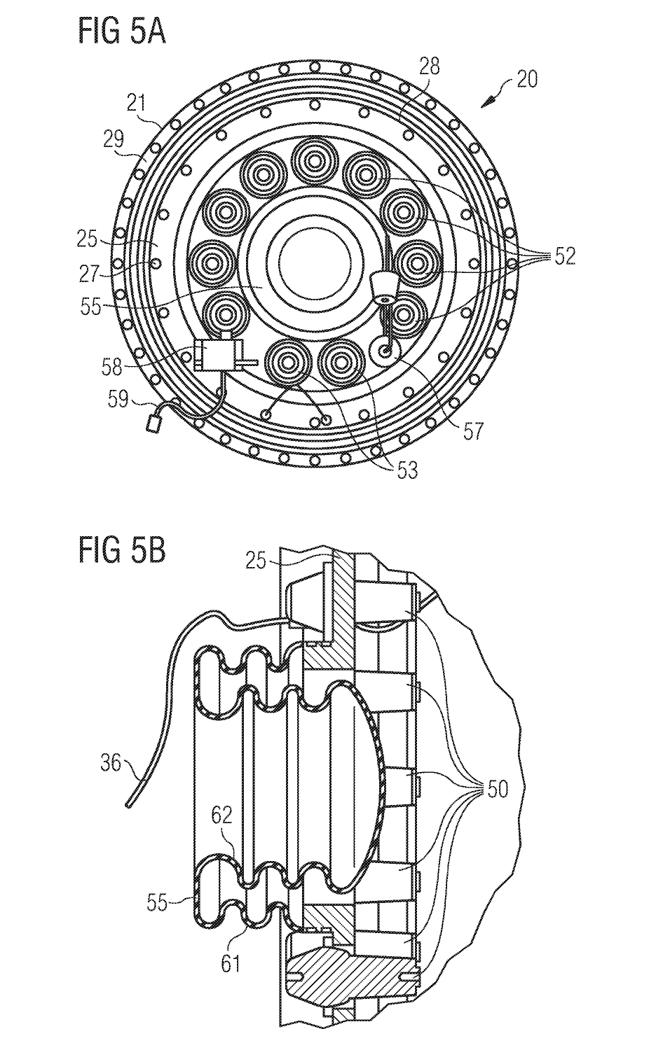

FIG. 5A shows a top view of the front portion of the subsea converter module 20, i.e. a view of the left hand end of the subsea converter module 20 of FIG. 4. Mounting portion 29 of subsea enclosure 21 is a circular flange with mounting holes surrounding the opening 28 in the subsea enclosure 21. On the flange and inside the mounting holes, a sealing portion in form of a seal seat, in particular in form of a groove is provided, as illustrated in the figure. A circumferential seal provided on the seal seat then seals the converter module to the base module when they are mounted to each other. The end wall 25 closes the opening 28, it is bolted by the bolts 27 to the internal flange 26. The pressure compensator 55 is arranged on a central portion of the end wall 25. The bushings 50 comprise the input bushings 52 and the output bushings 53. Bushings 52, 53 are circumferentially distributed around the pressure compensator 55.

The pressure compensator 55 constitutes a chamber to chamber pressure compensator, since it balances the pressure between the chamber formed by subsea enclosure 21 and the chamber formed by subsea enclosure 11 of the base module 10.

Furthermore, a valve 58 is mounted to the end plate 25. Valve 58 is configured so that by opening the valve 58, a fluid communication between the inside of the subsea converter module 20 and the inside of the base module 10 can take place. In some embodiments, valve 58 may be kept open during normal operation of the subsea converter, so that the fluid, in particular dielectric liquid, can freely circulate, thereby providing pressure compensation and avoiding operation of pressure compensator 55 (which remains in ‘standby’). In other configurations, valve 58 may be closed during normal operation.

Valve 58 is an electrically or hydraulically operated valve. Preferably, it is electrically operated. It may either have a normally open position, so that electric power needs to be applied to valve 58 to keep the valve 58 closed, or it may have a normally closed position, so that valve 58 is opened when electric power is applied to valve 58. In other configurations, it may be bi-stable, so that by applying electric power to valve 58, it may change its position from open to closed and vise versa. From supplying electric power to valve 58, the valve electrical connection 59 is provided. Connection 59 may include a connection to a battery, so that valve 58 can for example be kept closed when the subsea converter module 20 is assembled and stored prior to being mounted to a base module, for transportation and the like. It may furthermore include a power connection to system power of a respective subsea converter to which the subsea converter module 20 is mounted, so that during normal operation, the valve 58 can be operated and closed. It may for example be kept open during normal operation and can be closed in case of the occurrence of a fault and pollution of dielectric liquid within the base module. The electrical connection 59 may comprise two power cables with respective connectors, so that the well 58 can be connected to a battery and upon installation, the supply can be changed from battery to system power.

In the end plate 25, a bushing 57 for control signal feed-through, in particular for a optic fiber feed-through is provided. The bushing 57 may form part of the control connection 36 which supplies control signals from the base module through end wall 25 into the subsea converter module 20 to the individual converter units 30. The control connection 36 includes one or more optical fibers. In other embodiments, it may include one or more electrical conductors.

FIG. 5B shows an enlargement of a section of the subsea converter module 20 that is marked with a circle in FIG. 4B. The optical fiber of the control connection 36 and the bushings 50 penetrating the end wall 25 are clearly visible. As can be seen, the pressure compensator 55 surrounds an opening in the end wall 25. The opening is a central opening located in the center of the circular end wall 25. The pressure compensator 55 comprises a first bellows portion 61 which is mounted to the end wall 25 and which surrounds the opening in the end wall 25. It further includes a second bellows portion 62 which is folded back into the first bellows portion 61. Accordingly, a compact pressure compensator 55 that is capable of compensating relatively large volume variations and thus pressure differences can be obtained. The space or chamber formed between the first bellows portion 61 and the second bellows portion 62 is in fluid communication with the inside of the subsea enclosure 21 of the subsea converter module 20. The chamber formed by and surrounded by the second bellows portion 62, i.e. inside the second bellows portion 62, is in fluid communication with the inside of the base module 10 when the subsea converter module 20 is mounted thereto. If the fluid, in particular dielectric liquid, changes its volume inside the subsea enclosure 21, e.g. due to temperature changes or due to increased pressure, such volume changes cause a deformation of the bellows parts of pressure compensator 55, thereby avoiding the creation of a pressure difference across the pressure compensator 55. Furthermore, the base module 10 is generally pressure compensated against the ambient medium, so that when deployed subsea, the subsea pressure prevails inside the base module 10. Pressure compensator 55 transmits this pressure into the subsea enclosure 21. Accordingly, both the inside of subsea converter module 20 and base chamber 10 are at ambient pressure, i.e. at subsea pressure, so that the pressure difference across the walls of these modules are relatively low. In other embodiments, pressure compensator 55 may be configured differently. It may for example comprise a membrane across the opening in end wall 25, it may comprise a bladder that is mounted over the opening in end wall 25, or another type of flexible element that is capable of accommodating volume variations of the dielectric liquid filling the subsea enclosure 21.

The bushings 50 may be cast resin bushings comprising a conductor that is surrounded by an isolator, e.g. cast resin. Bushings 50 may for example be sheet metal bushings. Bushings 50 may be laser welded to the end wall 25. Other types of bushings and other mounting methods may also be employed. In some embodiments, a bushing may provide a feed-through for more than one electrical connection. A bushing may for example include three conductors for a three phase AC power feed through or two conductors for a DC feed through or a single phase AC feed through and the like.

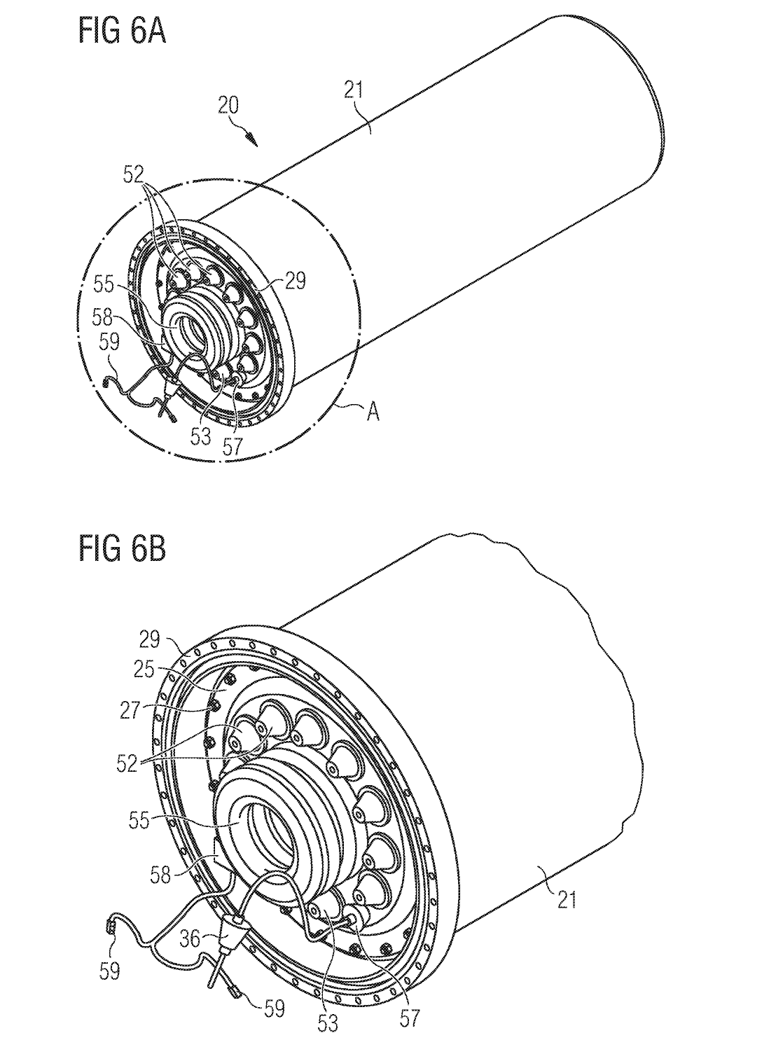

FIG. 6A is a perspective view of the subsea converter module 20 of FIG. 4. Mounting portion 29 in from of the flange surrounds the end wall 25 which is disk-shaped. As can be seen in the enlargement of the circled portion in FIG. 6B, the end wall 25 sits inside the cylindrical part of the subsea enclosure 21 and is mounted thereto by means of the bolts 27. Due to the compact configuration, the pressure compensator 55 only slightly protrudes from the subsea enclosure 21. The valve 58 is in FIG. 6 only partly visible due to pressure compensator 55, and the power connections 59 for supplying battery power or system power to valve 58 are shown.

In the embodiment of FIGS. 4 to 6, the subsea converter module 20 comprises three converter units 30, each receiving a three-phase power input. Accordingly, nine input bushings 52 are provided in the end wall 25. It should be clear that in other configurations, a different number of input bushings 52 may be provided in end plate 25 in accordance with a different number of converter units 30 within the subsea converter module 20. End wall 25 further includes two output bushings 53 for the single phase power output produced by the series connected converter units 30. It should be clear that in other configurations, a different number of output bushings 53 and respective output connections may be provided, for example three output bushings and three electrical power output connections for a three-phase power output, or four output bushings 53 for two single-phase electrical power outputs or the like.

End wall 25 provides separation towards the base module 10, i.e. it provides separation between the inside of subsea enclosure 21 of the subsea converter module 20 and the inside of the base module 10 to which it is mounted. Accordingly, it is possible to separate modules suffering from polluted medium and thus to stop faults from propagating to other subsea converter modules of the subsea converter. A failure or pollution in one of the converter modules 20 can be stopped by shutting off the fluid communication towards the dielectric liquid volume of the base module by closing the valve 58. The chamber to chamber pressure compensator 55 will then be operable to compensate pressure differences. By a bypass contactor system provided in the base module, it is furthermore possible to shut down power to any of the converter modules 20, thereby preventing electrical fault propagation.

Embodiments of the converter module 20 also allow the assembly and test of smaller subassemblies before assembling them to the main assembly, i.e. a subsea converter. After the subsea converter module 20 is assembled, the dielectric liquid filling the subsea enclosure 21 can be conditioned or dried, and the converter module can be sealed. Thus, the risk of exposure of electric components such as the capacitors of the converter units to air and/or humidity is reduced, thus increasing the reliability and the expected lifetime for these components. Also, if a fault is detected during assembly or final testing, the described embodiments allow the isolation of the faulty module and the performing of repairs without exposing the inside of the remaining converter modules to air and/or humidity. Since the subsea converter 100 may comprise a plurality of these converter modules 20, as illustrated in FIG. 2C, this is a significant advantage compared to a conventional configuration.

Embodiments of the converter module 20 further allow the assembling of the module and the storing of the module for long periods of time, before assembly into a larger unit. The converter module 20 is a standardized module that may be used with different configurations of the subsea converter 100. It may thus for example be mass-produced and stored for a prolonged period of time, for example for several months, before use. This may allow a more flexible and more standardized production, which may reduce the total costs of the converter module.

In the above embodiments, configurations are described in which the converter units within one converter module are connected in series, and the converter module provides a single phase AC power output. In other configurations, a single phase power output may be provided for each converter unit within the converter module. A series connection of the modules may then be done in the base module. In even other configurations, a converter unit of one converter module may be series connected with a converter unit of another converter module. In such configuration, if a converter module is lost (e.g. due to ingress of seawater or the like), only one converter unit in the series connection might be lost, which can be bypassed so that the respective output phase 103, 104, 105 can still be supplied with electric power from the remaining converter units.

While specific embodiments are disclosed herein, various changes and modifications can be made without departing from the scope of the invention. The present embodiments are to be considered in all respects as illustrative and non-restrictive, and all changes coming within the meaning and equivalency range of the appended claims are intended to be embraced therein.

1. A subsea converter module, comprising:
a subsea enclosure, configured to provide a fluid tight sealing of an inside of the subsea enclosure to an outside of the subsea enclosure;
at least one converter unit to provide frequency conversion of AC electrical power, the at least one converter unit being disposed in the subsea enclosure;
a mounting portion on the subsea enclosure, to mount the subsea converter module to a base module of a subsea converter, the subsea enclosure including an end wall providing separation towards the base module when the subsea converter module is mounted to the base module;
a sealing portion to seal the subsea enclosure to the base module;
a pressure compensator, mounted to the end wall and configured to provide pressure balancing between a medium present inside the subsea enclosure and a medium present outside the end wall of the subsea enclosure; and
electrical connections through the end wall to electrically contact the converter unit,
wherein the sealing portion is arranged so as to seal at least the part of the end wall, including the pressure compensator and the electrical connections, from a surrounding environment when the subsea converter module is mounted to the base module.

2. The subsea converter module of claim 1, further comprising:
a valve, provided at the end wall, the valve being configured to allow, in an open position, an exchange of fluid through the end wall.

3. The subsea converter module of claim 1, wherein the electrical connections through the end wall include at least an electrical power input connection to supply AC or DC electrical power to the at least one converter unit and an electrical power output connection for outputting converted AC or DC electrical power.

4. The subsea converter module of claim 3, wherein the electrical power input connection includes at least three electrical connections to supply three phase AC electrical power through the end wall, and wherein the electrical power output connection includes at least one or two electrical connections through the end wall to output at least single phase AC electrical power.

5. The subsea converter module of claim 1, wherein the electrical connections include penetrators or bushings, mounted in the end wall.

6. The subsea converter module of claim 1, further comprising:
a control connection through the end wall, to provide control signals to the converter unit.

7. The subsea converter module of claim 1, wherein the end wall is circular, wherein the pressure compensator is provided in the center of the end wall and wherein the electrical connections are provided in the end wall circumferentially around the pressure compensator.

8. The subsea converter module of claim 1, wherein the pressure compensator includes a flexible element for pressure compensation, the flexible element being selected from a group consisting of a bellows, a bladder or a membrane.

9. The subsea converter module of claim 1, wherein the pressure compensator comprises a first bellows portion mounted to the end wall and a second bellows portion folded back into the first bellows portion.

10. The subsea converter module of claim 1, wherein the subsea enclosure comprises a tank or a canister that is, apart from an opening, hermetically sealed, the opening being surrounded by the mounting portion and being closed and sealed by said end wall.

11. The subsea converter module of claim 1, wherein the subsea enclosure includes a tubular structure that is closed at one end and provided with the mounting portion in form of a mounting flange at the other end, the other end including an opening that is closed by the end wall, the end wall being provided by a circular plate mounted in the opening.

12. The subsea converter module of claim 1, wherein the subsea converter module is releasably mountable to the base module, and wherein the mounting portion is configured to form a fluid tight seal with the base module.

13. A subsea converter for providing a frequency conversion of AC electric power, comprising:
at least one of the subsea converter modules of claim 1.

14. The subsea converter of claim 13, further comprising
at least one base module including a subsea enclosure and electrical connections disposed within the subsea enclosure, wherein the at least one subsea converter module is coupled to the base module,
wherein the electrical connections of the base module are coupled to the electrical connections which lead through the end wall of the subsea converter module, and wherein the subsea enclosure of the subsea converter module is mounted to the subsea enclosure of the base module.

15. A method of assembling a subsea converter module, comprising:
providing a subsea enclosure, the subsea enclosure including a mounting portion to mount the subsea converter module to a base module of a subsea converter, and further including a sealing portion to seal the subsea enclosure to the base module;
disposing at least one converter unit, configured to provide frequency conversion of AC electrical power in the subsea enclosure;
providing an end wall of the subsea enclosure including electrical connections through the end wall to electrically contact the converter unit;
mounting a pressure compensator to the end wall, the pressure compensator being configured to provide pressure balancing; and
mounting the end wall to the subsea enclosure so as to provide a fluid tight sealing of an inside of the subsea enclosure to an outside of the subsea enclosure,
the sealing portion being arranged so as to seal at least the part of the end wall including the pressure compensator and the electrical connections from a surrounding environment when the subsea converter module is mounted to the base module.

16. The subsea converter module of claim 2, wherein the valve is an electrically or hydraulically or manually operated valve.

17. The subsea converter module of claim 2, wherein the electrical connections through the end wall include at least an electrical power input connection to supply AC or DC electrical power to the at least one converter unit and an electrical power output connection for outputting converted AC or DC electrical power.

18. The subsea converter module of claim 17, wherein the electrical power input connection includes at least three electrical connections to supply three phase AC electrical power through the end wall, and wherein the electrical power output connection includes at least one or two electrical connections through the end wall to output at least single phase AC electrical power.

19. The subsea converter module of claim 4, wherein the at least three electrical connections include at least three electrical connections per converter unit.

20. The subsea converter module of claim 18, wherein the at least three electrical connections include at least three electrical connections per converter unit.

21. The subsea converter module of claim 5, wherein the bushings are cast resin bushings.

22. The subsea converter module of claim 6, wherein the control connection is a fiber optic connection.

23. A subsea converter for providing a frequency conversion of AC electric power, comprising:
at least one of the subsea converter modules of claim 2.

24. The subsea converter of claim 23, further comprising:
at least one base module including a subsea enclosure and electrical connections disposed within the subsea enclosure, wherein the at least one subsea converter module is coupled to the base module,
wherein the electrical connections of the base module are coupled to the electrical connections which lead through the end wall of the subsea converter module, and wherein the subsea enclosure of the subsea converter module is mounted to the subsea enclosure of the base module.
